(19) United States
(12) Patent Application Publication
(10) Pub. No.: US 2009/0314338 A1
(43) Pub. Date: Dec. 24, 2009

(54) COATING FOR THIN-FILM SOLAR CELLS

(75) Inventors: Paul Alan BASORE, San Mateo, CA (US); Andreas BENTZEN, Oslo (NO); Erik SAUAR, Oslo (NO)

Correspondence Address: BIRCH STEWART KOLASCH & BIRCH, PO BOX 747, FALLS CHURCH, VA, 22040-0747, US

(73) Assignee: Renewable Energy Corporation ASA, Oslo (NO)

(21) Appl. No.: 12/487,106

(22) Filed: Jun. 18, 2009

Related U.S. Application Data
(60) Provisional application No. 61/073,832, filed on Jun. 19, 2008.

(51) Int. Cl. H01L 31/00; H01L 31/18

(52) U.S. Cl. 136/255; 438/72; 257/E21.211

(57) ABSTRACT

This invention relates to a method for producing thin film solar cells with a back-side reflective layer, wherein the solar module is a silicon thin film device placed in-between a back side planar substrate and a front side planar glass superstrate placed in parallel and a distance from the back side planar substrate, wherein the silicon thin film device comprises in successive order from the front side: a front side transparent conductive (TCO) layer, a multi junction thin-film solar conversion layer comprising amorphous and microcrystalline silicon or alloys thereof, a back side TCO-layer, a diffuse reflective layer with one or more local through-going apertures, and a metal layer covering the reflective layer and which is in contact with the back side TCO-layer through the one or more apertures in the reflective layer. The invention also relates to a method for forming the solar cell.

This invention relates to a method for producing thin film solar cells with a back-side reflective layer.

### BACKGROUND

The world supplies of fossil oil are expected to be gradually exhausted in the following decades. This means that our main energy source for the last century will have to be replaced within a few decades, both to cover the present energy consumption and the coming increase in the global energy demand.

In addition, there are raised many concerns that the use of fossil energy is increasing the Earth greenhouse effect to an extent that may turn dangerous. Thus the present consumption of fossil fuels should preferably be replaced by energy sources/carriers that are renewable and sustainable for our climate and environment. One such energy source is solar light, which irradiates the earth with vastly more energy than the present and any foreseeable increase in human energy consumption. However, solar cell electricity has up to date been too expensive to be competitive with nuclear power, thermal power etc. This needs to change if the vast potential of the solar cell electricity is to be realised.

The presently dominating production of photovoltaic devices is based on solar cells made from wafers of very pure monocrystalline or polycrystalline silicon. Such solar cells are sometimes referred to as first generation photovoltaic cells or bulk silicon cells. Present industrial bulk silicon cells may attain conversion efficiencies of 18-20%. However, the presently dominating production route involves sawing the silicon wafers from polycrystalline or monocrystalline ingots/blocks, a process which involves losing about ½ of the raw material as kerf remains. Another cost enhancing factor is that a silicon solar cell generates about 80% of its electric energy from the top 20 μm of the wafer thickness, and typical wafers thicknesses of present solar cells are 150-300 μm.

The low exploitation factor of the photovoltaic semiconductor raw material is a problem in that the production of highly pure silicon requires much energy and several refinement steps, leading to a very high cost. There is thus a need for making solar cells with significantly better exploitation of the expensive solar grade silicon than achievable with present wafer based solar cells.

### PRIOR ART

There has lately been an interest in thin film technology, where one or more thin layers of semiconductor material are deposited by chemical vapour deposition techniques onto a supporting substrate. This technology may provide huge cost savings due to significantly less use of photovoltaic material per unit area solar cell, and in that all process steps associated with casting of semiconductor grade silicon blocks/ingots and subsequent production of wafers may be omitted.

Thin film silicon solar cells employing layers of amorphous silicon have been commercially available for many years. These films have a rather low energy conversion rate (typically less than 8%) and they are encumbered with a tendency of degradation when exposed to sunlight, an apparent disadvantage for solar cells. However, there have recently been made significant improvements of this technology in stabilising and improving the energy conversion efficiencies for amorphous solar cells.

One approach is use of multi junction cells where one or more microcrystalline silicon layer(s) (μc-Si:H) are placed behind a front amorphous layer (a-Si:H). The amorphous silicon has a higher bandgap (1.7 eV) than crystalline silicon (1.1 eV), such that the amorphous silicon absorbs in the visible part of the solar spectrum, while the crystalline silicon absorbs the infrared part better. Each layer in the multi junction cell is laid directly on top of each other and each layer is given a stratified n-i-p doping.

This type of solar cell has an advantage in that all semiconductor layers including doped stratums may be produced for the entire solar module/panel in direct succession using low temperature plasma enhanced chemical vapour deposition (PECVD). Silane gas admixed with hydrogen gas will be decomposed and deposited as bulk phase (intrinsic) silicon, while silane admixed with hydrogen and trace gases with dopant elements will be decomposed and deposited as doped silicon. The choice of trace gas decides if the doped layer becomes n-type or p-type. A doped layer will typically have a thickness ranging from 2 nm up to about 50 nm, while the thickness of the bulk phase (intrinsic) silicon may be from 100 nm up to about 5 μm. Methane or germane gas can be introduced to shift the spectral response of the layer to shorter or longer wavelengths, respectively.

Multi junction cells form a serially connected stack of junctions, which is typically contacted by a conductive layer located on both the top and bottom surface of the stacked junctions. The front side conductive layer should be transparent in order to allow incident light penetrating into the semiconductor multi junction stack. There are different oxides available for this layer, and the layer is thus often denoted transparent conductive oxide, TCO, in the literature.

An example of a triple junction cell consisting of two n-i-p doped μc-Si:H layers and one n-i-p doped a-Si:H top layer made by hot wire chemical vapour deposition at about 250° C. is presented in Schropp et al. [1]. The layer structure of the cell is shown schematically in FIG. 1 of the present application, which is a facsimile of FIG. 1 of [1]. The bottom layer is a combined electric contact and supporting substrate made of stainless steel. Onto the SS-substrate there is deposited an approximately 50 nm thick n-doped μc-Si layer, then a 1320-1350 nm thick μc-Si layer, followed by p-doped μc-Si:H layer without specified thickness. This constitutes the first n-i-p doped μc-Si:H layer. Directly onto this layer, there is deposited a 20 nm thick n-doped layer followed by a 600-660 nm thick μc-Si:H and another p-doped μc-Si:H layer. This constitutes the second n-i-p doped μc-Si:H layer. Then there is deposited a n-doped a-Si:H layer with unspecified thickness, a 165 nm thick a-Si:H layer, and finally a p-doped a-Si:H layer with unspecified thickness. On top of the latter layer, a transparent conductive oxide of indium tin oxide is deposited. The thickness of the triple-junction cell is about 2 μm. The vapour deposition rates are typically from about 10 to about 60 nm per minute. The cell in [1] is reported to obtain an efficiency of 9.1%, and is presented as a good trade-off between cell efficiency and low manufacturing costs.

The efficiency of these thin film cells may be enhanced by use of light trapping in order to compensate for the intrinsically low absorbance of microcrystalline silicon, especially in the infrared wavelength range. Light trapping may be obtained by for example using a surface-textured transparent conductive oxide front contact combined with a highly reflective back contact.

An example of a tandem junction solar cell with light trapping is known from Yamamoto et al. [2]. The cell has a total thickness of about 2 μm and includes an intermediate layer between the a-Si and μc-Si cells that increases the amount of light trapping in the silicon. The structure of this cell, as seen from the front side, consists of a sheet of glass, TCO layer, a-Si:H cell, intermediate layer, μc-Si cell, and a back reflector. A module having an aperture area of 3825 cm² was produced using this structure. It had an initial efficiency of 13.1%. A smaller module having an area of 14 cm² and the same initial efficiency had a stabilized efficiency of 11.7% after 20 hours exposure to a high intensity xenon lamp.

Another example is known from two US patent publications to Sano et al., U.S. Pat. No. 6,835,888 and U.S. Pat. No. 7,064,263, which teaches a triple junction cell consisting of, as seen from the back side, a load carrying back substrate, a back contact metal layer, a transparent conductive oxide layer, two n-i-p doped microcrystalline layers, an n-i-p doped amorphous silicon layer, a front side transparent conductive oxide layer, and a front contact.

### OBJECTIVE OF THE INVENTION

The main objective of the invention is to provide highly efficient silicon thin film solar cells with superior light trapping.

Another objective of the invention is to provide a cost effective production method for highly efficient silicon thin film solar cells with superior light trapping.

The objective of the invention may be obtained by the features as set forth in the following description and/or in the appended claims.

### DESCRIPTION OF THE INVENTION

The invention is based on the realisation that superior light trapping may be obtained by inserting a layer with a high diffuse reflectance between the transparent conductive oxide layer and the metal layer on the back side of the semiconductor layers in an otherwise conventional silicon thin-film solar cell. The diffuse reflective layer improves light trapping compared to having metal directly in contact with the TCO for two reasons. Firstly, the diffuse reflective layer can have a higher optical reflectance at its interface with TCO than metal in contact with TCO. This benefit is especially seen when only those metals that are inexpensive and that adhere well to TCO are considered (e.g. nickel, chrome or aluminium). Secondly, a diffuse reflector redirects light from regions with poor light trapping to other regions that are likely to have better light trapping. In this way, the diffuse reflector compensates for deficiencies in the spatial uniformity of the front-surface texture. The invention is further based on the realisation that by depositing the diffuse reflective layer by use of ink-jet printing, it may be deposited onto the TCO-layer with the necessary openings required for obtaining electric contact between the metal and the TCO-layer. This approach to patterning the diffuse reflective layer has two primary benefits for the manufacturing of solar modules. Firstly, the formation of the diffuse reflective layer and the formation of the openings in this layer is all performed in the same step. Secondly, damage to the TCO-layer that would normally occur during the process of creating openings in the diffuse reflective layer is avoided.

Thus in a first aspect, the invention relates to a solar module, wherein the solar module is a silicon thin film device placed in-between a back side planar substrate and a front side planar glass superstrate placed in parallel and a distance from the back side planar substrate, wherein the silicon thin film device comprises in successive order from the front side:

a front side transparent conductive (TCO) layer,

a multi junction thin-film solar conversion layer comprising amorphous and microcrystalline silicon or alloys thereof,

a back side TCO-layer,

a diffuse reflective layer with one or more local through-going apertures, and

a metal layer covering the reflective layer and which is in contact with the back side TCO-layer through the one or more apertures in the reflective layer.

In a second aspect, the invention relates to a method for manufacturing multi junction silicon thin film solar modules, wherein the method comprises:

depositing a first layer of a transparent conductive oxide (TCO) on a glass substrate,

depositing a multi junction thin-film solar conversion layer comprised of amorphous and microcrystalline silicon or alloys thereof,

depositing a second TCO-layer,

ink-jet printing a diffuse reflective layer with one or more local through-going apertures, and

depositing a metal layer covering the reflective layer including the one or more apertures in the reflective layer.

The multi junction thin-film solar conversion layer may be formed of a stacked system comprising one or more stratified n-i-p doped amorphous silicon layer(s) and one or more stratified n-i-p doped microcrystalline silicon layer(s). The order of these stratified layers in the structure can be either n-i-p or p-i-n as long as all cells in the stack have the same polarity. The term “n-i-p” used herein refers to either the n-i-p or the p-i-n polarity.

The silicon thin-film may be divided into a number of narrow regions forming individual solar cells. This may e.g. be obtained by using a laser to ablate a groove through each layer individually after it is deposited, or in combination with the ablation of one or more previously deposited layers.

The invention may apply any known or conceivable configuration of the partitioning pattern into narrow regions/single cells. Examples of possible configurations are shown in FIG. 2, which is a facsimile of FIG. 3 of Yamamoto et al. [2]. These example configurations should not be considered as limiting the possible partitioning configurations.

A key advantage of ink-jet printing the reflective layer including local openings directly during the deposition of this layer is that the need for using chemical etching to make openings through the reflective layer is removed. An example of using chemical etching for form openings through a resin layer with high diffuse reflectance is, for example, described in a published US patent application by Young, US 20070007627. However, TCO-layers are easily damaged by use of chemical etching agents, a fact that has previously prevented the use of a TCO-diffuse reflector-metal structure on the back side of thin film solar cells/modules. The back side metal contact layer may be deposited by vapour deposition techniques, evaporation, sputtering etc. of a metallic phase onto the entire back side of the reflective coating. Suitable metals for vapour deposition include nickel, palladium, titanium, silver, gold, aluminium, copper, tungsten, vanadium, chromium, or any combination of these metals. Because the proposed structure relies primarily on the diffuse reflector layer to provide high internal back-surface reflectance, the optical reflectance of the metal is not critical and this allows a wide range of metals to be considered. The thickness of the deposited metal layer, or stacked system of metal layers, should advantageously have a total thickness in the range from 0.1 to 1 μm. Other possible techniques for depositing the metal layer(s) are electroless or electro plating. Suitable metals for plating include nickel, palladium, silver, gold, copper, chromium, tin, or any combination of these materials. The invention is not restricted to these choices of metals, it may apply using any material that provides a good electric contact with the underlying TCO layer, good electrical conductance, compatibility with the formation of contacts to carry the electric current to an external load, and resistance towards any disruptive force/physical condition associated with normal use of solar panels during the expected lifetime of a solar panel. This may include known electric conducting plastics and/or other polymer formulations such as carbon polymers, etc.

The diffuse reflective layer should have as high a reflectivity as possible for the wavelengths of the solar spectrum that are not fully absorbed by the multi junction thin-film solar conversion layers on the first pass of the light through these layers, but which can be absorbed by these layers during subsequent passes of the light through those layers. The diffuse reflective layer should also be UV-resistant and temperature resistant up to temperatures normally encountered during operation of a solar panel during the expected lifetime of a solar panel. Suitable materials for ink-jet deposition of a diffuse reflective layer include, but are not limited to polyamide, sulfo-polyester, polyketone, polyester, and acrylic resins in aqueous or solvent solution. These materials can be made reflective by loading them with a white pigment such as sub-micrometer particles of titanium dioxide. The thickness of the reflective layer may be from about 1 μm to about 20 μm.

The pattern of openings in the diffuse reflective layer is adjusted to minimize the combined optical and electrical losses associated with contact between the metal and TCO layers. These contacts need to be few and far between to obtain the maximum benefit from the improved light trapping provided by the diffuse reflective layer, but they need to be numerous and closely spaced to minimize the electrical resistance loss due to lateral current flow in the back-side TCO. A typical coverage fraction for the openings is between about 1% and 10% with spacing between contacts between about 100 μm and 1 mm.

The transparent conductive oxide may be any solid oxide that is transparent to visible and infra-red light and which is electrically conductive. The front side TCO-layer may advantageously be surface textured in order to enhance the light trapping capacities of the solar cell. Suitable transparent conductive oxides includes, but are not limited to, SnO₂:F, ZnO:Al, and In₂O₃:Sn. These TCO materials are deposited either by physical vapour deposition or by chemical vapour deposition. In both cases a low-pressure oxygen-containing atmosphere is normally used to obtain the desired properties. Glass sheets already coated with a textured TCO layer are available as a standard product for solar applications.

The amorphous silicon and the multicrystalline silicon that form the multi junction thin-film solar conversion layers may be deposited by use of any known or conceivable technique that is compatible with TCO-coated glass. Possible techniques include, but are not limited to, plasma enhanced chemical vapour deposition (PECVD), hot wire chemical vapour deposition, very high frequency plasma enhanced chemical vapour deposition, sputtering, or electron-beam deposition. Only PECVD has been developed to the scale required for commercial production in solar applications, but research continues in the other techniques, which offer the potential for faster deposition and/or reduced equipment cost.

By the term “low temperature chemical vapour deposition” we mean a temperature in the deposition chamber below about 400° C.

By the term “amorphous silicon or a-Si”, we mean a non-crystalline form of silicon made by decomposing silicon-containing gases and depositing the formed silicon phase on a substrate. The amorphous silicon consists of a more or less randomly oriented network of tetrahedral silicon. In order to eliminate certain defects formed by non-tetrahedral silicon atoms in the network, the amorphous silicon may advantageously be hydrogenated by either using a silicon-containing gas compound that includes hydrogen atoms, or by admixing hydrogen gas in the deposition chamber. Commonly, silane gas (SiH₄) is used for this purpose. The symbol for hydrogenated amorphous silicon is a-Si:H. The doped stratums in the a-Si phase may be made by adding trace amounts of gases containing the dopant elements in the gas mixture in the deposition chamber.

By the term “microcrystalline silicon or μc-Si”, we mean an allotropic form of silicon similar to amorphous silicon, except for small (sub-micrometer) crystalline grains within the amorphous phase. When the grains are smaller than about 100 nm, microcrystalline silicon is also termed as nanocrystalline silicon (nc-Si) in the literature. Nanocrystalline silicon may be used interchangeably with microcrystalline silicon in this invention. Also μc-Si may advantageously be hydrogenated to form μc-Si:H by ensuring that hydrogen atoms are included in the gases introduced into the deposition chamber. Microcrystalline silicon, including doped stratums, are commonly formed by the same process as for amorphous silicon, but either with the introduction of additional hydrogen gas or use of a higher temperature in the deposition chamber. For PECVD deposition, the volumetric flow of hydrogen is normally 20 to 50 times the flow of silane.

The thickness of the a-Si layer should be in the range from about 50 nm to about 500 nm, preferably from about 100 to about 300 nm. The thickness of the μc-Si layer(s) should be in the range from about 0.5 μm to about 5 μm, preferably from about 1.5 μm to about 3 μm.

By the term “doped stratum” we mean a layer within the a-Si or the μc-Si phase which is loaded with one or more doping elements to form a n-type or a p-type doped silicon phase. The term “n-i-p” means a silicon phase with a n-type stratum, a stratum layer of non-doped silicon, and a stratum of p-type doped silicon. The order of these layers in the structure can be either n-i-p or p-i-n as long as all cells in the stack have the same polarity. The term “n-i-p” used here refers to either the n-i-p or the p-i-n polarity.

As used herein, the term “front side” denotes the side of the solar cell/module that is facing the sun when the solar panel is in operation. The term “back side” is the opposite side of the front side of the solar cell/module.

### LIST OF FIGURES

FIG. 1 is a facsimile of FIG. 1 in [1] showing an example of the solar conversion layer of a triple junction solar cell.

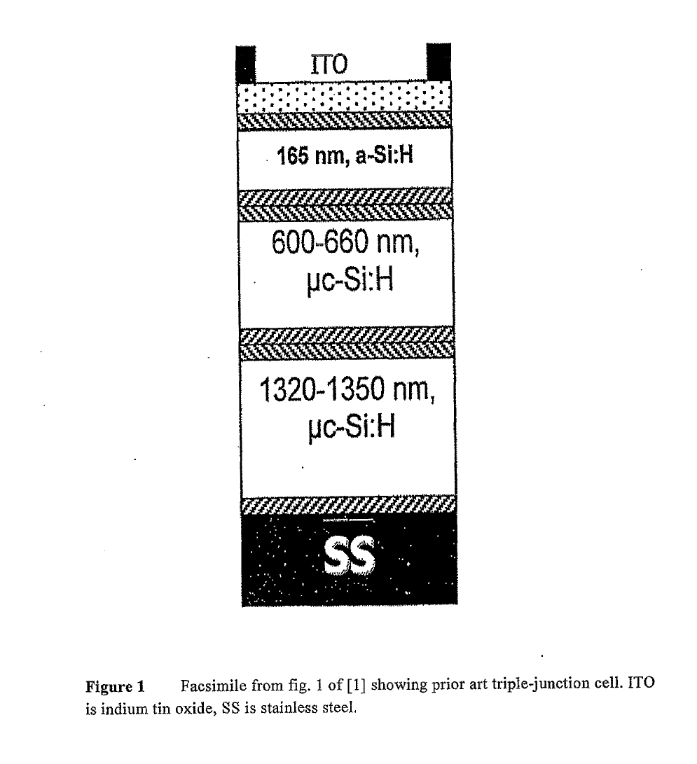

FIG. 2 is a facsimile of FIG. 3 in [2] showing examples of possible cell configurations.

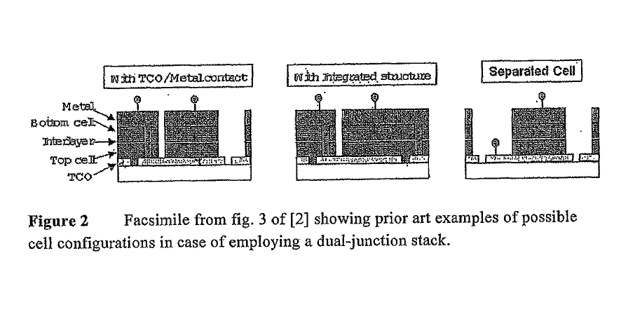

FIG. 3 is a schematic side view of a section of an example embodiment of the invention.

### EXAMPLE EMBODIMENT OF THE INVENTION

The invention will be described in more detail by way of an example of an embodiment of the invention. The example should not be considered a limitation of the general inventive idea of using a diffuse reflective layer in-between the back side TCO and metallic layer. Any configuration of multi junction solar conversion layers using a TCO, a diffuse reflective layer, and a metallic layer on the back side of the solar conversion layers is included in the invention.

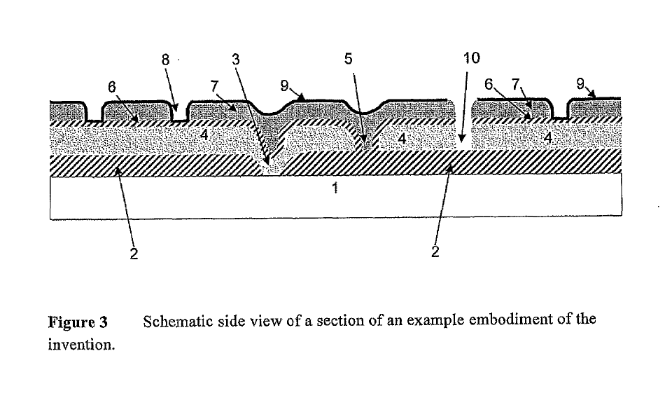

A side view of a section of the example embodiment is shown schematically in FIG. 3. A front side glass substrate 1 carries a layer of front side transparent conductive oxide 2 which is divided into a series of local regions defining solar cells by parallel grooves or openings 3 in the TCO layer (the figure shows only a section with one groove 3). On top of the TCO layer 2 a solar conversion layer 4 is deposited, the solar conversion layer covers also the grooves 3. The solar conversion layer of the example embodiment is a triple junction cell comprising one front side amorphous n-i-p doped amorphous silicon layer and two n-i-p doped microcrystalline silicon layers as the solar conversion layers, these layers are not shown in the figure, the solar conversion layer is shown as one single phase. The solar conversion layer is locally removed to form access openings 5 to the front side TCO 2. A back side transparent conductive oxide layer 6 is placed onto the solar conversion layer 4 including local openings 5. On top of the back side TCO layer 6 a diffuse reflective coating 7 is laid such that a set of local openings 8 is formed to allow access to the back side TCO layer 6. A metallic layer 9 is then deposited covering the diffuse reflective coating 7 including openings 8. An electric separation 10 is formed in the form of a groove 10 extending in parallel at a distance apart from each groove 3; the groove 10 is formed by local removal of all layers except the front side TCO layer 2.

The example embodiment may be formed as follows: A planar sheet 1 of glass is coated over the entirety of one surface with a layer 2 of transparent conducting oxide (TCO) of fluorine-doped tin oxide that is about 1 um thick and has an electrical sheet resistance of about 10 ohms per square. The free surface of the TCO is rough on a micrometer scale. This rough surface is not shown in the figure for sake of clarity. The rough surface gives the TCO-coated glass a hazy appearance. Suitable TCO-coated glass can be purchased as a commercially available product. A pulsed infrared laser is used to scribe a set of parallel lines/grooves 3 through the TCO coating 2 extending along the length of the glass 1. These lines are spaced about 10 mm apart. They define the boundaries of the solar cells that will later be interconnected electrically in series, so the spacing determines the voltage-to-current ratio for the panel.

The panel is washed with a mild detergent that removes laser-scribe debris and any accumulated dust but does not damage the TCO layer 2. The panel is then loaded into a sequence of PECVD deposition chambers for deposition of the layers of amorphous and microcrystalline silicon that form the active photovoltaic absorber 4. Although more than one layer can be deposited in a single chamber, the use of multiple chambers allows the geometry and process conditions of each chamber to be optimized for a particular layer. The n-i-p structure of each layer in this particular embodiment is formed by depositing the p-type stratum first, followed by the intrinsic stratum and then the n-type stratum. The details of cleaning and silicon deposition by PECVD are well known to those skilled in this art.

The silicon-coated sheet is laser-scribed a second time, this time using a pulsed green laser that is absorbed much more strongly by the silicon than the TCO. The laser beam passes through the glass 1 and TCO 2, and then ablates the silicon 4 while the TCO 2 remains at least partially intact. Using this method, a set of parallel lines/grooves 5 is scribed in the silicon as close as practical to the TCO scribes 3 without intersecting or crossing over the TCO scribes 3. These lines 5 need not be continuous, and are typically scribed as a dotted line with dot spacing of around 100 μm. The purpose of these scribes is to create openings to the underlying TCO layer 2, so it is only necessary to remove enough silicon along these lines to allow adequate electrical contact through these openings.

A second ‘backside’ TCO layer 6 of aluminium-doped zinc oxide is deposited onto the panel. This TCO layer 6 may be thinner and with less sheet conductance than the ‘frontside’ TCO layer 2 so as to reduce its cost and minimize detrimental optical absorption. A typical thickness is 200 nm with a sheet conductance of 100 ohms per square. This TCO 6 needs to have enough sheet conductance to carry the cell's current with low resistance loss in the regions of the cell in-between the metal contacts 8.

Ink-jet printing is used to deposit a white polymer coating 7 on the surface, leaving 50 μm diameter holes 8 in the coating 7 spaced about 150 μm apart, so that about 90% of the surface is covered with the white polymer to provide high internal reflectance and good light trapping. The white coating is about 10 μm thick, depending on the specific properties of the polymer used and the ink-jet droplet size. The polymer coating is then heated to remove any residual volatile components.

A thin layer of metal 9 is next deposited onto the entire surface of the panel. This metal makes contact to the backside TCO 6 through the holes 8 in the white coating. This metal may typically be aluminum and 100 nm thick, giving it a sheet resistance of about 0.4 ohms per square. This excellent sheet conductance works in parallel with the backside TCO 6 to collect the cell's current and conduct it to the adjacent cell with minimum resistive power loss. The metal also reflects any light that might penetrate through the white coating.

A final set of parallel laser scribes 10 form lines/grooves that are parallel to the two previous sets of laser scribe lines (3, 5). These scribes 10 need to be as close to the silicon scribes 5 as possible without intersecting or crossing over the silicon scribes. A pulsed green laser is used and is incident through the glass 1. As with the previous laser scribe, the laser passes through the front side TCO 2 but is absorbed in the silicon 4 which is heated to vaporization. The ablating silicon blows away from the sheet, taking with it the overlying layers of backside TCO 6, white polymer 7, and thin metal 9. In this way, electrical separation between adjacent cells is accomplished, the only remaining link being the front side TCO 2, which remains at least partially intact at the base of these scribe lines.

This completes the formation of the cells and their series connection to form a monolithically interconnected solar panel. Subsequent processing is required to electrically isolate the perimeter, connect the cells to a junction box, and to laminate a rear sheet to protect the active layers from damage and for safety purposes. These finishing process steps are well known to those skilled in the art of producing photovoltaic modules.

### REFERENCES

1. R. E. I. Schropp et al., “First Hot-Wire Deposited Triple Junction Silicon Thin Film Solar Cell”, Proceedings of the 3^{rd} World Conference on Photovoltaic Energy Conversion, Osaka, May 2003.
2. K. Yamamoto et al., “Thin Film Silicon Solar Cell and Module”, Conf. Record of the 31^{st} IEEE Photovoltaic Specialists Conf., Lake Buena Vista, Fla., January 2005.

1. Solar module, wherein the solar module is a silicon thin film device placed in-between a back side planar substrate and a front side planar glass superstrate (1) placed in parallel and a distance from the back side planar substrate, wherein the silicon thin film device comprises in successive order from the front side:
a front side transparent conductive (TCO) layer (2),
a multi junction thin-film solar conversion layer (4) comprising amorphous and microcrystalline silicon or alloys thereof,
a back side TCO-layer (6),
a diffuse reflective layer (7) with one or more local through-going apertures (8), and
a metal layer (9) covering the reflective layer (7) and which is in contact with the back side TCO-layer (6) through the one or more apertures (8) in the reflective layer (7).

2. Solar module according to claim 1,
wherein the amorphous and microcrystalline silicon of the multi junction thin-film solar conversion layer (4) are formed as a stacked system
comprising one or more stratified n-i-p doped amorphous silicon layer(s) and one or more stratified n-i-p doped microcrystalline silicon layer(s).

3. Solar module according to claim 1,
wherein the amorphous and microcrystalline silicon of the multi junction thin-film solar conversion layer (4) are formed as a stacked system comprising one or more stratified p-i-n, doped amorphous silicon layer(s) and one or more stratified p-i-n, doped microcrystalline silicon layer(s).

4. Solar module according to claim 1,
wherein the diffuse reflective layer (7) is made of one or more of the following materials: polyamide, sulfo-polyester, polyketone, polyester, and acrylic resins, and where the materials have been made reflective by loading them with a white pigment such as sub-micrometer particles of titanium dioxide.

5. Solar module according to claim 4,
wherein the diffuse reflective layer (7) has thickness from about 1 μm to about 20 μm.

6. Solar module according to claim 1,
wherein the back side metallic layer (9) is made of one or more of the following materials: nickel, palladium, titanium, silver, gold, aluminium, copper, tungsten, vanadium, chromium, tin, or any combination of these metals, electric conducting plastics and/or other electric conducting polymer formulations such as carbon polymers.

7. Solar module according to claim 6,
wherein the back side metallic layer (9) has a total thickness in the range from 0.1 to 1 μm.

8. Solar module according to claim 1,
wherein the transparent conductive oxide (2, 6) is one or more of the following materials: SnO₂:F, ZnO:Al, and In₂O₃:Sn.

9. Solar module according to claim 5,
wherein the pattern of openings (8) in the diffuse reflective layer (7) is adjusted to form a coverage fraction for the openings between 1% and 10% with spacing between contacts between 100 μm and 1 mm.

10. Method for manufacturing silicon thin film modules,
wherein the method comprises:
depositing a first layer of a transparent conductive oxide (TCO) on a glass substrate,
depositing a multi junction thin-film solar conversion layer comprised of amorphous and microcrystalline silicon or alloys thereof,
depositing a second TCO-layer,
ink-jet printing a diffuse reflective layer with one or more local through-going apertures, and
depositing a metal layer covering the reflective layer including the one or more apertures in the reflective layer.

11. Method according to claim 10,
wherein the wherein the amorphous and microcrystalline silicon of the multi junction thin-film solar conversion layer are formed as a stacked system comprising one or more stratified n-i-p doped amorphous silicon layer(s) and one or more stratified n-i-p doped microcrystalline silicon layer(s) by use of one or more of the following techniques: plasma enhanced chemical vapour deposition, hot wire chemical vapour deposition, very high frequency plasma enhanced chemical vapour deposition, sputtering, or electron-beam deposition.

12. Method according to claim 10,
wherein the wherein the amorphous and microcrystalline silicon of the multi junction thin-film solar conversion layer are formed as a stacked system comprising one or more stratified p-i-n doped amorphous silicon layer(s) and one or more stratified p-i-n doped microcrystalline silicon layer(s) by use of one or more of the following techniques: plasma enhanced chemical vapour deposition, hot wire chemical vapour deposition, very high frequency plasma enhanced chemical vapour deposition, sputtering, or electron-beam deposition.

13. Method according to claim 10,
wherein the diffuse reflective layer is deposited into the back side transparent oxide layer by ink-jet printing an aqueous or solvent solution of one or more of the following materials; polyamide, sulfo-polyester, polyketone, polyester, and acrylic resins, and where the solution is loaded with a white pigment such as sub-micrometer particles of titanium oxide.

14. Method according to claim 13,
wherein
the diffuse reflective layer is deposited to form a coverage fraction for the openings between 1% and 10% with spacing between contacts between 100 μm and 1 mm, and where
the thickness of the formed diffuse reflective layer is from 1 μm to 20 μm.

15. Method according to claim 10,
wherein
the metallic layer is made of one or more of the following materials: nickel, palladium, titanium, silver, gold, aluminium, copper, tungsten, vanadium, chromium, tin, or any combination of these metals, and which
are deposited by vapour deposition techniques, evaporation, sputtering, or electroless or electro plating to a total thickness in the range from 0.1 to 1 μm.

16. Method according to claim 10,
wherein
the transparent conductive oxide is one or more of the following materials: SnO₂:F, ZnO:Al, and In₂O₃:Sn deposited by use of physical or chemical vapour deposition.

17. Solar module according to claim 2,
wherein the diffuse reflective layer (7) is made of one or more of the following materials: polyamide, sulfo-polyester, polyketone, polyester, and acrylic resins, and where the materials have been made reflective by loading them with a white pigment such as sub-micrometer particles of titanium dioxide.

18. Solar module according to claim 3,
wherein the diffuse reflective layer (7) is made of one or more of the following materials: polyamide, sulfo-polyester, polyketone, polyester, and acrylic resins, and where the materials have been made reflective by loading them with a white pigment such as sub-micrometer particles of titanium dioxide.

19. Solar module according to claim 2,
wherein the back side metallic layer (9) is made of one or more of the following materials: nickel, palladium, titanium, silver, gold, aluminium, copper, tungsten, vanadium, chromium, tin, or any combination of these metals, electric conducting plastics and/or other electric conducting polymer formulations such as carbon polymers.

20. Solar module according to claim 3,
wherein the back side metallic layer (9) is made of one or more of the following materials: nickel, palladium, titanium, silver, gold, aluminium, copper, tungsten, vanadium, chromium, tin, or any combination of these metals, electric conducting plastics and/or other electric conducting polymer formulations such as carbon polymers.
